(19) United States
(12) Patent Application Publication
(10) Pub. No.: US 2024/0332240 A1
(43) Pub. Date: Oct. 3, 2024

(54) PANEL-LEVEL PACKAGE STRUCTURE AND METHOD FOR PREPARING THE SAME

(71) Applicant: JIANGSU PANGU SEMICONDUCTOR TECHNOLOGY CO., LTD, Nanjing (CN)

(72) Inventors: Zhiyi XIAO, Nanjing (CN); Shuying MA, Nanjing (CN); Jiao WANG, Nanjing (CN)

(73) Assignee: JIANGSU PANGU SEMICONDUCTOR TECHNOLOGY CO., LTD, Nanjing (CN)

(21) Appl. No.: 18/743,604

(22) Filed: Jun. 14, 2024

Related U.S. Application Data
(63) Continuation of application No. PCT/CN2022/118688, filed on Sep. 14, 2022.

(30) Foreign Application Priority Data
Dec. 15, 2021 (CN) 202111537150.2
Dec. 15, 2021 (CN) 202123150765.8
May 27, 2022 (CN) 202221291175.9

(51) Int. Cl. H01L 23/00; H01L 23/31; H01L 23/538; H01L 25/065; H01L 25/10

(52) U.S. Cl. CPC H01L 24/29; H01L 23/3107; H01L 24/32; H01L 24/83; H01L 25/0655; H01L 25/105; H01L 23/5385; H01L 24/16; H01L 2224/16; H01L 2224/28105; H01L 2224/29011; H01L 2224/29012; H01L 2224/32145; H01L 2224/8309

(57) ABSTRACT

A panel-level package structure includes a bonding layer; and a first temporary carrier and a second temporary carrier oppositely disposed on both sides of the bonding layer. Both the first temporary carrier and the second temporary carrier are connected to the bonding layer, and at least one bonding cavity is jointly formed by the bonding layer, the first temporary carrier and the second temporary carrier, so that integral package with a relatively large area may be achieved, which further improves package efficiency, thus reducing a package cost. A package structure with a double-sided symmetrical design may make products evenly stressed, which not only effectively solves problems of warping in products, but also greatly improves preparing efficiency, thus reducing a cost.

### CROSS-REFERENCE TO RELATED APPLICATIONS

The present application is a continuation of International Application No. PCT/CN2022/118688, filed on Sep. 14, 2022, which claims priority to Chinese Patent Application No. 202111537150.2, filed on Dec. 15, 2021, Chinese Patent Application No. 202123150765.8, filed on Dec. 15, 2021, and Chinese Patent Application No. 202221291175.9, filed on May 27, 2022. The aforementioned applications are hereby incorporated by reference in their entireties.

### TECHNICAL FIELD

The present application relates to the field of panel-level package technologies, and in particular, to a panel-level package structure and a method for preparing the same.

### BACKGROUND

As mobile consumption electronic products such as mobile phones, computers, or digital cameras have higher and higher requirements on functional integration, large storage space, high reliability and miniaturization package, a high-density micro-electronic package technology has become a mainstream of a new generation of electronic products. In order to cooperate with the development of the electronic products, chips used in the electronic products are developing towards a relatively high density, a relatively fast speed, a relatively small size and a relatively low cost. However, with the increasing variety of functions in current electronic products, the number of Input/Output (I/O) ports of a fan-in package structure cannot meet the requirements of the electronic products. Therefore, it is necessary to provide a new package structure to accommodate more numbers of I/O ports, reduce a size and a thickness of a chip, and integrate more heterogeneous chips.

### SUMMARY

In order to solve the forgoing technical problems, the present application provides a panel-level package structure and a method for preparing the same, so that integral package with a relatively large area can be achieved, which further improves package efficiency, thus reducing a package cost. During a package process, adopting a package structure with a double-sided symmetrical design may make products evenly stressed, which not only effectively solves problems of warping in products, but also greatly improves preparing efficiency, thus reducing a cost.

In order to achieve the foregoing purposes, a first aspect of the present application provides a panel-level package structure. The panel-level package structure includes a bonding layer; and a first temporary carrier and a second temporary carrier oppositely disposed on both sides of the bonding layer. Both the first temporary carrier and the second temporary carrier are connected to the bonding layer, and at least one bonding cavity is jointly formed by the bonding layer, the first temporary carrier and the second temporary carrier.

In at least one embodiment of the present application, the first temporary carrier is connected to the second temporary carrier through the bonding layer, to form an integral composite panel, and the integral composite panel is flat.

In at least one embodiment of the present application, the bonding layer adopts a closed structure, and an interior of the at least one bonding cavity has a vacuum negative pressure.

In the panel-level package structure provided by the present application, integral package with a relatively large area can be achieved, which further improves package efficiency, thus reducing a package cost. During a package process, adopting a package structure with a double-sided symmetrical design may make products evenly stressed, which not only effectively solves problems of warping in products, but also greatly improves preparing efficiency, thus reducing a cost.

In at least one embodiment of the present application, the bonding layer is circumferentially disposed along a position of a periphery of the first temporary carrier or a position of a periphery of the second temporary carrier, to bond the first temporary carrier and the second temporary carrier into an integral composite panel.

In at least one embodiment of the present application, the bonding layer includes a first bonding layer, and the first bonding layer adopts a closed pattern.

In at least one embodiment of the present application, the bonding layer further includes a second bonding layer, the second bonding layer is disposed at an interior enclosed by the first bonding layer, and a cavity located at the interior enclosed by the first bonding layer is divided into regions by the second bonding layer.

In at least one embodiment of the present application, the cavity located at the interior enclosed by the first bonding layer is equally divided into at least four equally-divided bonding cavities by the second bonding layer.

In at least one embodiment of the present application, the cavity located at the interior enclosed by the first bonding layer is equally divided into two equally-divided bonding cavities by the second bonding layer along a direction of a diagonal of the interior enclosed by the first bonding layer.

In at least one embodiment of the present application, at least one rectangular second bonding layer is disposed centered on a center point of the interior enclosed by the first bonding layer.

In at least one embodiment of the present application, four corners of the interior enclosed by the first bonding layer are respectively disposed with the second bonding layer having a rectangular shape.

In at least one embodiment of the present application, the first temporary carrier and the second temporary carrier respectively include a plastic package layer, a chip is disposed on the plastic package layer, and a plurality of chip conductive bumps are connected to the chip.

In at least one embodiment of the present application, an exhaust part is disposed on the bonding layer, to form a non-closed bonding layer, so that an air pressure inside the at least one bonding cavity and an air pressure outside the at least one bonding cavity are consistent.

In at least one embodiment of the present application, the exhaust part includes a plurality of exhaust grooves, and the plurality of exhaust grooves are disposed at four corners of the non-closed bonding layer or at a middle position of the non-closed bonding layer.

In at least one embodiment of the present application, the exhaust part includes a plurality of exhaust holes, and the plurality of exhaust holes are evenly disposed on the non-closed bonding layer.

In at least one embodiment of the present application, the non-closed bonding layer is circumferentially disposed along a position of a periphery of the first temporary carrier or a position of a periphery of the second temporary carrier, to bond the first temporary carrier and the second temporary carrier into an integral composite panel enclosed on all sides.

In at least one embodiment of the present application, the non-closed bonding layer includes a first non-closed bonding layer and a second non-closed bonding layer, the first non-closed bonding layer is circumferentially disposed along a position of a periphery of the first temporary carrier or a position of a periphery of the second temporary carrier, the second non-closed bonding layer is disposed at an interior enclosed by the first non-closed bonding layer, and the interior enclosed by the first non-closed bonding layer is divided into regions by the second non-closed bonding layer, to bond the first temporary carrier and the second temporary carrier into an integral composite panel.

In at least one embodiment of the present application, a cavity located at the interior enclosed by the first non-closed bonding layer is equally divided into at least four equally-divided bonding cavities by the second non-closed bonding layer, and the exhaust part is disposed at a center position of an interior of the first non-closed bonding layer.

In at least one embodiment of the present application, at least one rectangular second non-closed bonding layer is disposed centered on a center point of the interior enclosed by the first non-closed bonding layer.

In at least one embodiment of the present application, the first temporary carrier and the second temporary carrier respectively include a plastic package layer, an insulating layer and a carrier sheet are sequentially disposed on the plastic package layer, and at least two chips are disposed between the insulating layer and the plastic package layer.

In at least one embodiment of the present application, the first temporary carrier and the second temporary carrier respectively include a plurality of chip conductive bumps, and the at least two chips are connected to the plurality of chip conductive bumps.

In at least one embodiment of the present application, a structure of the first temporary carrier and a structure of the second temporary carrier are the same, the first temporary carrier and the second temporary carrier are disposed in parallel, and the first temporary carrier and the second temporary carrier are symmetric relative to the bonding layer.

The present application further provides a method for preparing a panel-level package structure, the method for preparing the panel-level package structure includes coating a bonding layer on a first temporary carrier or a second temporary carrier, and pressing the first temporary carrier and the second temporary carrier into an integral composite panel, an interior of the integral composite panel comprising at least one bonding cavity jointly formed by the bonding layer, the first temporary carrier and the second temporary carrier; separating carrier sheets oppositely disposed on surfaces of the integral composite panel, to form a bonding board; and after preparation of the bonding board is finished, separating, by a cutting manner, temporary bonding layers on the bonding board, to obtain the panel-level package structure.

In at least one embodiment of the present application, an interior of the at least one bonding cavity has a vacuum negative pressure; and the coating a bonding layer on a first temporary carrier or a second temporary carrier includes: coating the bonding layer circumferentially along a position of a periphery of the first temporary carrier or a position of a periphery of the second temporary carrier; or coating a first bonding layer circumferentially along a position of a periphery of the first temporary carrier or a position of a periphery of the second temporary carrier, and disposing a second bonding layer at an interior enclosed by the first bonding layer, the interior enclosed by the first bonding layer being divided into regions by the second bonding layer.

In at least one embodiment of the present application, an exhaust part is disposed on the bonding layer; and the coating a bonding layer on a first temporary carrier or a second temporary carrier includes: coating a non-closed bonding layer circumferentially along a position of a periphery of the first temporary carrier or a position of a periphery of the second temporary carrier; or coating a first non-closed bonding layer circumferentially along a position of a periphery of the first temporary carrier or a position of a periphery of the second temporary carrier, and disposing a second non-closed bonding layer at an interior enclosed by the first non-closed bonding layer, the interior enclosed by the first non-closed bonding layer being divided into regions by the second non-closed bonding layer.

In at least one embodiment of the present application, the pressing the first temporary carrier and the second temporary carrier into an integral composite panel includes: closing and pressing the first temporary carrier and the second temporary carrier by a vacuum bonding device, so that the at least one bonding cavity can be formed between the first temporary carrier and the second temporary carrier.

### BRIEF DESCRIPTION OF THE DRAWINGS

FIG. 1 is a schematic structural diagram of a temporary carrier according to at least one embodiment of the present application.

FIG. 2 is a schematic structural diagram of an integral composite panel according to at least one embodiment of the present application.

FIG. 3 is a schematic structural diagram of a panel-level package structure according to at least one embodiment of the present application.

FIG. 4 is a schematic structural diagram of a panel-level package structure formed with multiple circuit layers according to at least one embodiment of the present application.

FIG. 5 is a schematic cross-sectional diagram of a panel-level package structure according to at least one embodiment of the present application.

FIG. 6 is a schematic structural diagram of a bonding layer disposed circumferentially along a position of a periphery of a first temporary carrier or a position of a periphery of a second temporary carrier according to at least one embodiment of the present application.

FIG. 7 is a schematic structural diagram of an interior enclosed by a first bonding layer being equally divided into four equally-divided bonding cavities by a second bonding layer along a direction parallel to a sidewall of the first bonding layer according to at least one embodiment of the present application.

FIG. 8 is a schematic structural diagram of an interior enclosed by a first bonding layer being equally divided into eight equally-divided bonding cavities by a second bonding layer along a direction parallel to a sidewall of the first bonding layer according to at least one embodiment of the present application.

FIG. 9 is a schematic structural diagram of an interior enclosed by a first bonding layer being equally divided into two equally-divided bonding cavities by a second bonding layer along a direction of a diagonal of the interior enclosed by the first bonding layer according to at least one embodiment of the present application.

FIG. 10 is a schematic structural diagram of a plurality of rectangular second bonding layers being disposed centered on a center point of an interior enclosed by a first bonding layer according to at least one embodiment of the present application.

FIG. 11 is a schematic structural diagram of rectangular second bonding layers being respectively disposed at four corners of an interior enclosed by a first bonding layer according to at least one embodiment of the present application.

FIG. 12 is a schematic cross-sectional diagram of a panel-level package structure according to at least one embodiment of the present application.

FIG. 13 is a schematic structural diagram of a non-closed bonding layer circumferentially disposed along a position of a periphery of a first temporary carrier or a position of a periphery of a second temporary carrier according to at least one embodiment of the present application.

FIG. 14 is a schematic structural diagram of a non-closed bonding layer circumferentially disposed along a position of a periphery of a first temporary carrier or a position of a periphery of a second temporary carrier according to at least one embodiment of the present application.

FIG. 15 is a schematic structural diagram of a non-closed bonding layer circumferentially disposed along a position of a periphery of a first temporary carrier or a position of a periphery of a second temporary carrier according to at least one embodiment of the present application.

FIG. 16 is a schematic structural diagram of an interior enclosed by a first non-closed bonding layer being equally divided into at least four equally-divided bonding cavities by a second non-closed bonding layer along a direction parallel to a sidewall of the first non-closed bonding layer according to at least one embodiment of the present application.

FIG. 17 is a schematic structural diagram of an interior enclosed by a first non-closed bonding layer being equally divided into at least four equally-divided bonding cavities by a second non-closed bonding layer along a direction parallel to a sidewall of the first non-closed bonding layer according to at least one embodiment of the present application.

FIG. 18 is a schematic structural diagram of a plurality of rectangular second bonding layers disposed centered on a center point of an interior enclosed by a first bonding layer according to at least one embodiment of the present application.

FIG. 19 is a flowchart of a method for preparing a panel-level package structure according to at least one embodiment of the present application.

FIG. 20 is a flowchart of a method for preparing a panel-level package structure according to at least one embodiment of the present application.

FIG. 21 is a flowchart of a method for preparing a panel-level package structure according to at least one embodiment of the present application.

### DETAILED DESCRIPTIONS OF THE EMBODIMENTS

It should be noted that words such as “first” and “second” are used to define parts, which are merely intended to distinguish corresponding parts, and unless otherwise stated, the above words have no special meaning, and therefore, the above words cannot be understood as a limitation to the protection scope of the present application.

A Fan-out (FO) package structure as a type of wafer-level package has many advantages such as a large number of input/output ports and high integration flexibility (such as the ability to achieve multi-chip integration in a vertical direction and in a horizontal direction), and therefore, the Fan-out package structure is commonly used for multi-chip package, ultra-thin package, three-dimensional system-level package or the like. The appearance of Wafer-level Fan-out package (WLFOP) greatly increases the number of I/O ports of a package body, and matches with a development direction of multifunctionality of a chip. Due to an increasing demand of the market, in order to break a size limitation of an existing wafer, a PCB-level preparation concept is combined with a semiconductor wafer-level package method, so as to package consumer, high-speed computing and professional electronic products, so that the requirement for package miniaturization is achieved, and preparing efficiency is improved, thus effectively reducing a preparing cost.

In order to further reduce a cost, manufacturers start to use a panel with a relatively large size as a carrier. The appearance of a panel-level fan-out package technology can effectively achieve integral package with a relatively large area, which further improves package efficiency, thus reducing a package cost, so that there is a relatively wide development prospect. At present, a silicon wafer of 300*300 mm² may be used to produce approximately 600 ICs, and if the panel-level fan-out package technology is used, the number of ICs packaged on a panel of 500*500 mm² may be up to 2600, i.e., package yield on the panel of 500*500 mm² is more than four times fan-out package yield on the wafer of 300*300 mm². Therefore, a cost may be effectively reduced, and competitiveness of products is increased. The panel-level fan-out package technology has many advantages such as a relatively low cost, a flexible design, a good electric heating property, diverse commercial models and wide application fields. However, a package structure with a single-sided design is used in an existing panel-level fan-out package technology. Since during a preparing process, products may have problems of warping due to uneven stress distribution in the panel-level fan-out package structure with the single-sided design, preparing efficiency is greatly reduced, thus increasing a preparing cost.

In view of this, at least one embodiment of the present application provides a panel-level package structure, to solve the technical problems of uneven stress distribution in a panel-level fan-out package structure with a single-sided design. The panel-level package structure includes a bonding layer; and a first temporary carrier and a second temporary carrier oppositely disposed on both sides of the bonding layer. The bonding layer is connected to the first temporary carrier and the second temporary carrier, respectively, and at least one bonding cavity is jointly formed by the bonding layer, the first temporary carrier and the second temporary carrier.

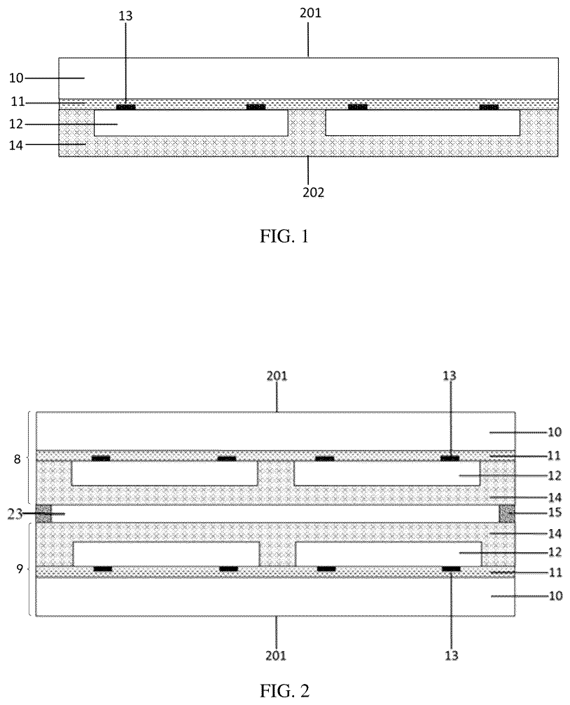

In at least one embodiment of the present application, the bonding cavity adopts a closed structure, and an interior of the bonding cavity has a vacuum negative pressure. The panel-level package structure is described below with reference to FIG. 1 to FIG. 11.

As shown in FIG. 1, a temporary carrier provided by the present application includes a plastic package layer 14. A chip 12, a temporary bonding layer 11 and a carrier sheet 10 are sequentially disposed on the plastic package layer 14. A plurality of chip conductive bumps 13 are connected to the chip 12. A material of the carrier sheet 10 is one or a combination of silicon, glass, metal, and an organic material. In this embodiment, the material of the carrier sheet 10 is preferably metal. A first surface 202 of the plastic package layer 14 is disposed away from the carrier sheet 10 and is used to connect to a bonding layer. A surface 201 of the carrier sheet 10 is disposed away from the temporary bonding layer 11.

As shown in FIG. 2, an integral composite panel (also known as an integrated composite structure) provided by the present application includes a first temporary carrier 8 and a second temporary carrier 9. A structure of the first temporary carrier 8 and a structure of the second temporary carrier 9 are the same, which may refer to the temporary carrier shown in FIG. 1 for details. A bonding layer 15 is disposed between the first temporary carrier 8 and the second temporary carrier 9. That is to say, the first temporary carrier 8 and the second temporary carrier 9 are symmetrically disposed on two sides of the bonding layer 15. The bonding layer 15 is disposed between the first surface 202, away from the carrier sheet 10, of the plastic package layer 14 of the first temporary carrier 8 and the first surface 202, away from the carrier sheet 10, of the plastic package layer 14 of the second temporary carrier 9. The first temporary carrier 8 is connected to the second temporary carrier 9 through the bonding layer 15, to form the integral composite panel, so that the integral composite panel is flat. A shape of the bonding layer 15 may be annular, a bonding cavity 23 is jointly enclosed by the bonding layer 15, the plastic package layer 14 of the first temporary carrier 8 and the plastic package layer 14 of the second temporary carrier 9, and an interior of the bonding cavity 23 has a vacuum negative pressure. The negative pressure of the bonding cavity 23 may be used to enhance a binding force between the first temporary carrier 8 and the second temporary carrier 9, and therefore, the first temporary carrier 8 and the second temporary carrier 9 may be stably bonded under a condition that a contact area between the bonding layer 15 and the first temporary carrier 8 is relatively small. Moreover, setting the relatively small contact area between the bonding layer 15 and the first temporary carrier 8 may facilitate the separation of the first temporary carrier 8 and the second temporary carrier 9 in a subsequent process.

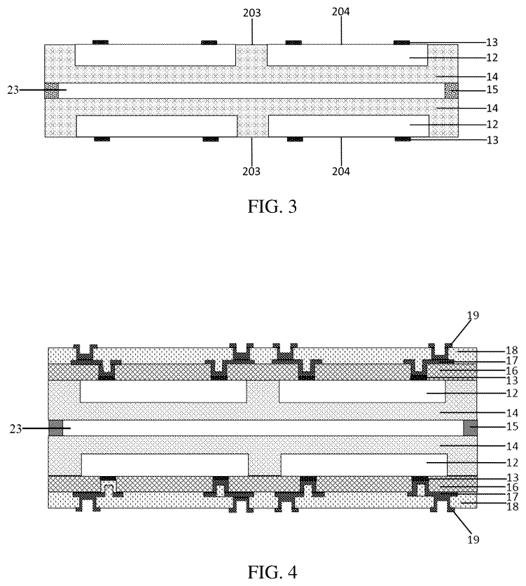

As shown in FIG. 3, the panel-level package structure provided by the present application is a structure obtained after the carrier sheets 10 and the temporary bonding layers 11 both on surfaces of the integral composite panel are separated. After the carrier sheets 10 and the temporary bonding layers 11 are separated, a surface 204, facing the temporary bonding layer 11, of the chip 12 and a second surface 203, facing the temporary bonding layer 11, of the plastic package layer 14 are exposed. The integral composite panel includes the first temporary carrier 8 and the second temporary carrier 9. The bonding layer 15 is disposed on the first temporary carrier 8 or the second temporary carrier 9, the first temporary carrier 8 is connected to the second temporary carrier 9 through the bonding layer 15 by means of a closed connection, to form the integral composite panel, so that the integral composite panel is flat. The bonding layer 15 has a hollow mass, for example, the shape of the bonding layer 15 may be annular. The bonding cavity 23 is jointly enclosed by the bonding layer 15, the first temporary carrier 8 and the second temporary carrier 9, and the interior of the bonding cavity 23 has the vacuum negative pressure. Specifically, the carrier sheets 10 oppositely disposed on the surfaces of the integral composite panel are detached, to form a bonding board; and after preparation of the bonding board is finished, the panel-level package structure is obtained by separating the temporary bonding layers 11 on the bonding board.

FIG. 4 shows a structure obtained after multiple circuit layers are formed on the panel-level package structure provided by the present application. Taking the multiple circuit layers being formed on the panel-level package structure by a re-wiring process as an example, the multiple circuit layers include an insulating layer and a circuit layer. The insulating layer includes a first insulating layer 16 and a second insulating layer 18, and the first insulating layer 16 and the second insulating layer 18 are sequentially disposed on the plastic package layer 14. The circuit layer includes a first circuit layer 17 and a second circuit layer 19, the first circuit layer 17 is connected to the chip conductive bump 13, and the second circuit layer 19 is connected to the first circuit layer 17. A material of the insulating layer is an inorganic material or an organic material. A material of the circuit layer may be any one or more of aluminum, copper, nickel or gold, and may also be a combination of a plurality of metals.

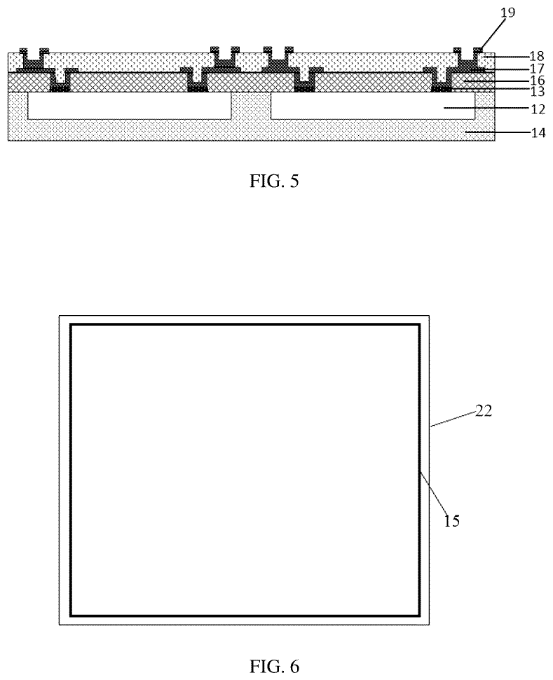

As shown in FIG. 4 and FIG. 5, two fan-out structures shown in FIG. 5 are obtained after a structure (i.e. the structure shown in FIG. 4) is separated along the bonding cavity 23, and the structure is obtained after the multiple circuit layers are formed on the panel-level package structure. The interior of the bonding cavity has the vacuum negative pressure, which not only makes a separation effect good, but also improves separation efficiency.

FIG. 6 is a schematic structural diagram of a bonding layer 15 disposed along a position of a periphery of the first temporary carrier 8 or a position of a periphery of the second temporary carrier 9 according to the present application. The thick solid line represents a position of the bonding layer 15, and the thin solid line represents the position of the periphery 22 of the first temporary carrier 8 or the position of the periphery 22 of the second temporary carrier 9. The bonding layer 15 is disposed between the first temporary carrier 8 and the second temporary carrier 9, so that the first temporary carrier 8 and the second temporary carrier 9 can be bonded into the integral composite panel. A shape of an outer periphery of the bonding layer 15 is substantially the same as that of the first temporary carrier 8, and a size of the outer periphery of the bonding layer 15 is slightly less than that of the first temporary carrier 8. That is to say, the outer periphery of the bonding layer 15 is close to the position of the periphery 22 of the first temporary carrier 8. Moreover, a size of an inner periphery of the bonding layer 15 is less than that of the outer periphery of the bonding layer 15, i.e., the shape of the bonding layer 15 is a rectangular ring.

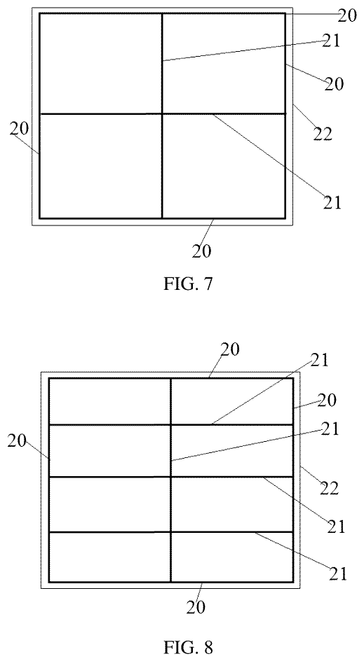

FIG. 7 is a schematic structural diagram of an interior enclosed by a first bonding layer 20 being equally divided into four equally-divided bonding cavities 23 by a second bonding layer 21 along a direction parallel to a sidewall of the first bonding layer 20 according to the present application. As shown in FIG. 7, the thick solid line represents a position of the bonding layer (for example, the first bonding layer 20 or the second bonding layer 21), and the thin solid line represents a position of a periphery 22 of the first temporary carrier 8 or a position of a periphery 22 of the second temporary carrier 9. The first bonding layer 20 is circumferentially disposed along the position of the periphery 22 of the first temporary carrier 8 or the position of the periphery 22 of the second temporary carrier 9, and the interior enclosed by the first bonding layer 20 is equally divided into four equally-divided bonding cavities 23 by the second bonding layer 21 along the direction parallel to the sidewall of the first bonding layer 20. That is to say, a shape of the first bonding layer 20 is annular, an outline of the first bonding layer 20 is substantially the same as that of the first temporary carrier 8, and a size of the outline of the first bonding layer 20 is slightly less than that of the first temporary carrier 8. In this embodiment, both a shape of an outer periphery of the first bonding layer 20 and a shape of an inner periphery of the first bonding layer 20 are substantially square, and the second bonding layer 21 includes a connecting line for connecting midpoints of two opposite edges of the inner periphery of the first bonding layer 20.

FIG. 8 is a schematic structural diagram of an interior enclosed by a first bonding layer 20 being equally divided into eight equally-divided bonding cavities 23 by a second bonding layer 21 along a direction parallel to a sidewall of the first bonding layer 20 according to the present application. As shown in FIG. 8, the thick solid line represents a position of the bonding layer (for example, the first bonding layer 20 or the second bonding layer 21), and the thin solid line represents a position of a periphery 22 of the first temporary carrier 8 or a position of a periphery 22 of the second temporary carrier 9. The first bonding layer 20 is circumferentially disposed along the position of the periphery 22 of the first temporary carrier 8 or the position of the periphery 22 of the second temporary carrier 9, and the interior enclosed by the first bonding layer 20 is equally divided into eight equally-divided bonding cavities 23 by the second bonding layer 21 along the direction parallel to the sidewall of the first bonding layer 20. That is to say, a shape of the first bonding layer 20 is annular, an outline of the first bonding layer 20 is substantially the same as that of the first temporary carrier 8, and a size of the outline of the first bonding layer 20 is slightly less than that of the first temporary carrier 8. In this embodiment, both a shape of an outer periphery of the first bonding layer 20 and a shape of an inner periphery of the first bonding layer 20 are substantially square. An area of the interior enclosed by the inner periphery of the first bonding layer 20 is equally divided in half by one second bonding layer 21 along a first direction, and an area of the interior enclosed by the inner periphery of the first bonding layer 20 is equally divided in four by three second bonding layers 21 along a second direction. The first direction is a direction parallel to a group of two opposite edges of the square, and the second direction is a direction parallel to another group of two opposite sides of the square.

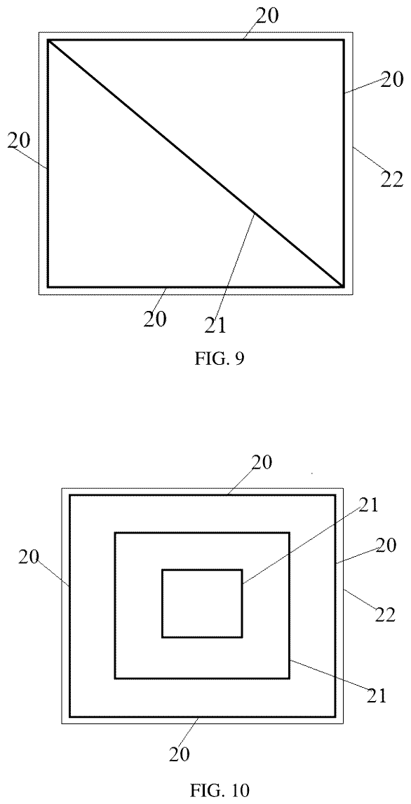

FIG. 9 is a schematic structural diagram of an interior enclosed by a first bonding layer 20 being equally divided into two equally-divided bonding cavities 23 by a second bonding layer 21 along a direction of a diagonal of the interior enclosed by the first bonding layer 20 according to the present application. As shown in FIG. 9, the thick solid line represents a position of the bonding layer (for example, the first bonding layer 20 or the second bonding layer 21), and the thin solid line represents a position of a periphery 22 of the first temporary carrier 8 or a position of a periphery 22 of the second temporary carrier 9. The first bonding layer 20 is circumferentially disposed along the position of the periphery 22 of the first temporary carrier 8 or the position of the periphery 22 of the second temporary carrier 9, and the interior enclosed by the first bonding layer 20 is equally divided into two equally-divided bonding cavities 23 by the second bonding layer 21 along the direction of the diagonal of the interior enclosed by the first bonding layer 20.

FIG. 10 is a schematic structural diagram of a plurality of rectangular second bonding layers 21 being disposed centered on a center point of an interior enclosed by a first bonding layer 20 according to the present application. As shown in FIG. 10, the thick solid line represents a position of the bonding layer (for example, the first bonding layer 20 or the second bonding layer 21), and the thin solid line represents a position of a periphery 22 of the first temporary carrier 8 or a position of a periphery 22 of the second temporary carrier 9. The first bonding layer 20 is circumferentially disposed along the position of the periphery 22 of the first temporary carrier 8 or the position of the periphery 22 of the second temporary carrier 9, and two rectangular second bonding layers 21 are disposed centered on the center point of the interior enclosed by the first bonding layer 20.

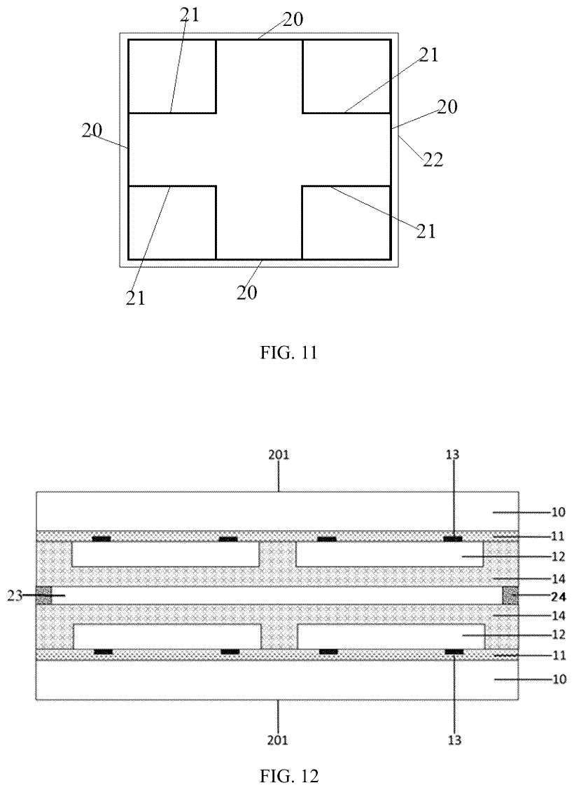

FIG. 11 is a schematic structural diagram of rectangular second bonding layers 21 being respectively disposed at four corners of an interior enclosed by a first bonding layer 20 according to the present application. As shown in FIG. 11, the thick solid line represents a position of the bonding layer (for example, the first bonding layer 20 or the second bonding layer 21), and the thin solid line represents a position of a periphery 22 of the first temporary carrier 8 or a position of a periphery 22 of the second temporary carrier 9. The first bonding layer 20 is circumferentially disposed along the position of the periphery 22 of the first temporary carrier 8 or the position of the periphery 22 of the second temporary carrier 9, and the rectangular second bonding layers 21 are respectively disposed at four corners of the interior enclosed by the first bonding layer 20.

The first bonding layer 20 is circumferentially disposed along the position of the periphery 22 of the first temporary carrier 8 or the position of the periphery 22 of the second temporary carrier 9, and the second bonding layer 21 is disposed at the interior enclosed by the first bonding layer 20, to divide the interior enclosed by the first bonding layer 20 into regions. The second bonding layer 21 is disposed at the interior enclosed by the first bonding layer 20, so that a bonding area may be increased, thus making the bonding between the first temporary carrier 8 and the second temporary carrier 9 relatively stable. Manners of disposing the second bonding layer 21 are not limited to the manners shown in FIG. 7 to FIG. 11, and changes in a shape of the second bonding layer 21 fall within the protection scope of the present application.

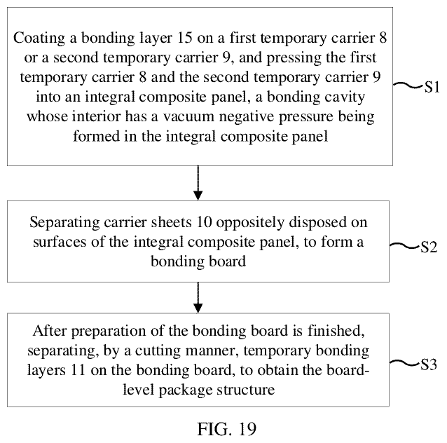

At least one embodiment of the present application provides a method for preparing a panel-level package structure. As shown in FIG. 19, the method includes the following steps S1 to S3.

S1: coating a bonding layer 15 on a first temporary carrier 8 or a second temporary carrier 9, and pressing the first temporary carrier 8 and the second temporary carrier 9 into an integral composite panel, a bonding cavity whose interior has a vacuum negative pressure being formed in the integral composite panel.

S2: separating carrier sheets 10 oppositely disposed on surfaces of the integral composite panel, to form a bonding board.

S3: after preparation of the bonding board is finished, separating, by a cutting manner, temporary bonding layers 11 on the bonding board, to obtain the panel-level package structure.

The coating a bonding layer 15 on a first temporary carrier 8 or a second temporary carrier 9 in the step S1 further includes the following step:
coating the bonding layer 15 circumferentially along a position of a periphery of the first temporary carrier 8 or a position of a periphery of the second temporary carrier 9; or
coating a first bonding layer 20 circumferentially along a position of a periphery of the first temporary carrier 8 or a position of a periphery of the second temporary carrier 9, and disposing a second bonding layer 21 at an interior enclosed by the first bonding layer 20, the interior enclosed by the first bonding layer 20 being divided into regions by the second bonding layer 21.

The pressing the first temporary carrier 8 and the second temporary carrier 9 into an integral composite panel in the step S1 further includes the following step:
closing and pressing the first temporary carrier 8 and the second temporary carrier 9 by a vacuum bonding device, so that at least one bonding cavity whose interior has the vacuum negative pressure is formed between the first temporary carrier 8 and the second temporary carrier 9.

In a vacuum negative pressure environment, the first temporary carrier 8 and the second temporary carrier 9 are closed and pressed by the vacuum bonding device, which can make the interior of the bonding cavity have the vacuum negative pressure during a pressing process.

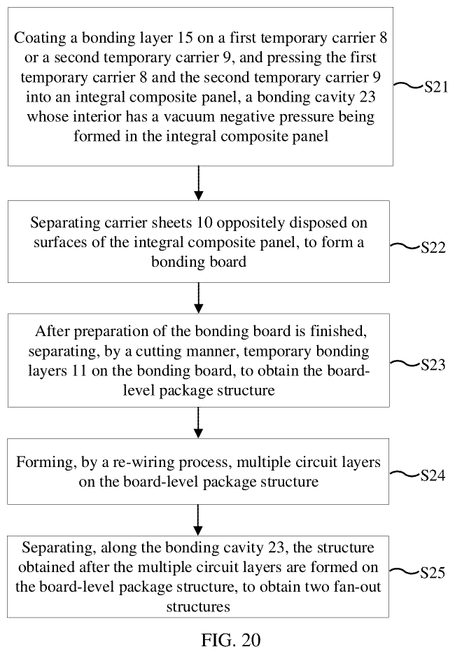

At least one embodiment of the present application provides a method for preparing a panel-level package structure. As shown in FIG. 20, the method includes the following steps S21 to S25.

S21: coating a bonding layer 15 on a first temporary carrier 8 or a second temporary carrier 9, and pressing the first temporary carrier 8 and the second temporary carrier 9 into an integral composite panel, a bonding cavity 23 whose interior has a vacuum negative pressure being formed in the integral composite panel.

S22: separating carrier sheets 10 oppositely disposed on surfaces of the integral composite panel, to form a bonding board.

S23: after preparation of the bonding board is finished, separating, by a cutting manner, temporary bonding layers 11 on the bonding board, to obtain the panel-level package structure.

S24: forming, by a re-wiring process, multiple circuit layers on the panel-level package structure. A first insulating layer 16 and a second insulating layer 18 are sequentially disposed on a plastic package layer 14. A first line layer 17 is connected to a chip conductive bump 13, and a second line layer 19 is connected to the first line layer 17, to obtain a structure obtained after the multiple circuit layers are formed on the panel-level package structure.

S25: separating, along the bonding cavity 23, the structure obtained after the multiple circuit layers are formed on the panel-level package structure, to obtain two fan-out structures.

In order to solve technical problems of explosion of a vacuum cavity and bulging of a vacuum cavity in a high-temperature baking environment, at least one embodiment of the present application provides a panel-level package structure with a connection between an interior and an exterior. A bonding cavity between a first bonding carrier and a second bonding carrier is connected to the exterior. The panel-level package structure is described below with reference to FIG. 1 to FIG. 5 and FIG. 12 to FIG. 18.

As shown in FIG. 12, differences between the panel-level package structure provided in this embodiment and the panel-level package structure in the foregoing embodiments are that a non-closed bonding layer 24 is disposed on a first temporary carrier 8 or a second temporary carrier 9. That is to say, the bonding layer 15 in FIG. 2 is non-closed. The specific structure of the first temporary carrier 8 or the second temporary carrier 9 may refer to the structure shown in FIG. 1 to FIG. 5 in the foregoing embodiments, and details are not described herein again. The first temporary carrier 8 is connected to the second temporary carrier 9 through the non-closed bonding layer 24, to form the integral composite panel, so that the integral composite panel is flat. Both the first temporary carrier 8 and the second temporary carrier 9 are connected to the non-closed bonding layer 24, so that the bonding cavity 23 is formed in the integral composite panel. An exhaust part is disposed on the bonding layer 15 in FIG. 2, to form the non-closed bonding layer 24 having the exhaust part, and disposal of the non-closed bonding layer 24 makes an air pressure inside the bonding cavity 23 and an air pressure outside the bonding cavity 23 consistent. In this way, integral package with a relatively large area can be achieved, which further improves package efficiency, thus reducing a package cost, and problems of warping in products are effectively solved while solving the technical problems of easy bulging of a package structure and explosion of a vacuum bonding cavity, thus improving security of chip package and yield of products.

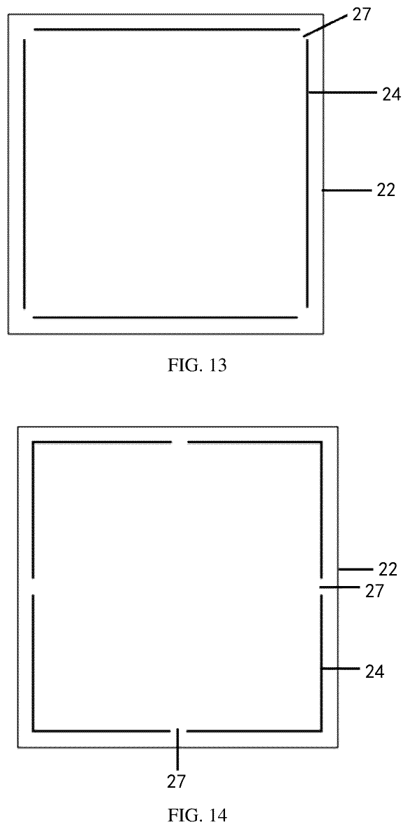

As shown in FIG. 13, in an implementation of at least one embodiment of the present application, the non-closed bonding layer 24 is circumferentially disposed along a position of a periphery 22 of the first temporary carrier 8 or a position of a periphery 22 of the second temporary carrier 9. Preferably, the exhaust part includes a plurality of exhaust grooves 27, and the plurality of exhaust grooves 27 are disposed at four corners of the bonding layer 15 in FIG. 6, to form the non-closed bonding layer 24 having the plurality of exhaust grooves 27. In FIG. 13, the thick solid line represents a position of the non-closed bonding layer 24, and the thin solid line represents the position of the periphery 22 of the first temporary carrier 8 or the position of the periphery 22 of the second temporary carrier 9.

A shape of the non-closed bonding layer 24 is substantially the same as a shape of the periphery 22 of the first temporary carrier 8 or a shape of the periphery 22 of the second temporary carrier 9. Both the shape of the non-closed bonding layer 24 and one of the shape of the periphery 22 of the first temporary carrier 8 and the shape of the periphery 22 of the second temporary carrier 9 are square. A perimeter of the periphery 22 of the first temporary carrier 8 or a perimeter of the periphery 22 of the second temporary carrier 9 is greater than a perimeter of the non-closed bonding layer 24, and a center and a center line of the first temporary carrier 8 or a center and a center line of the second temporary carrier 9 are substantially coincides with a center and a center line of an interior enclosed by the non-closed bonding layer 24, respectively. Setting the non-closed bonding layer 24 with a symmetrical structure may facilitate even stress distribution on surfaces of the first temporary carrier 8 and the second temporary carrier 9. In addition, a difference between the perimeter of the non-closed bonding layer 24 and one of the perimeter of the periphery 22 of the first temporary carrier 8 or the perimeter of the periphery 22 of the second temporary carrier 9 is less than a preset value, i.e., the non-closed bonding layer 24 is close to the position of the periphery 22 of the first temporary carrier 8 or the position of the periphery 22 of the second temporary carrier 9 as much as possible. In this way, warping in the periphery of the first temporary carrier 8 and warping in the periphery of the second temporary carrier 9 may be further avoided.

The plurality of exhaust grooves 27 are disposed at four corners of the non-closed bonding layer 24, and distances of any two pairs of adjacent exhaust grooves 27 are basically equal, which may make stress distribution on the surfaces of the first temporary carrier 8 and the second temporary carrier 9 relatively even, so as to avoid the warping on the surfaces of the first temporary carrier 8 and the second temporary carrier 9.

The non-closed bonding layer 24 is disposed circumferentially along the position of the periphery 22 of the first temporary carrier 8 or the position of the periphery 22 of the second temporary carrier 9, to bond the first temporary carrier 8 and the second temporary carrier 9 into the integral composite panel. In this way, integral package with a relatively large area can be achieved, which further improves package efficiency, thus reducing a package cost, and problems of warping in products are effectively solved while solving the technical problems of easy bulging of a package structure and explosion of a vacuum bonding cavity, thus improving security of chip package and yield of products.

As shown in FIG. 14, in an implementation of at least one embodiment of the present application, the non-closed bonding layer 24 is circumferentially disposed along a position of a periphery 22 of the first temporary carrier 8 or a position of a periphery 22 of the second temporary carrier 9. The exhaust part includes a plurality of exhaust grooves 27, and the plurality of exhaust grooves 27 are disposed at middle positions of the bonding layer 15 in FIG. 6, to form the non-closed bonding layer 24 having the plurality of exhaust grooves 27. In FIG. 14, the thick solid line represents a position of the non-closed bonding layer 24, and the thin solid line represents the position of the periphery 22 of the first temporary carrier 8 or the position of the periphery 22 of the second temporary carrier 9.

The plurality of exhaust grooves 27 are disposed at a midpoint of each of four edges of the non-closed bonding layer 24, so that stress distribution on surfaces of the first temporary carrier 8 and the second temporary carrier 9 may be relatively even, thus effectively solving problems of warping in products.

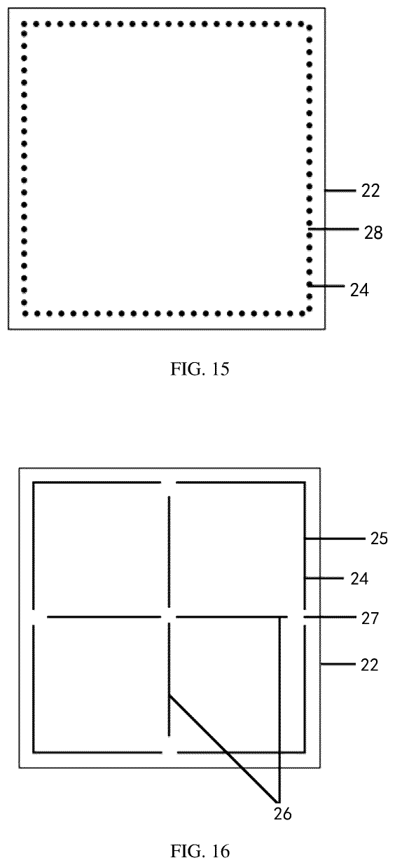

As shown in FIG. 15, in an implementation of at least one embodiment of the present application, the non-closed bonding layer 24 is circumferentially disposed along a position of a periphery 22 of the first temporary carrier 8 or a position of a periphery 22 of the second temporary carrier 9. The exhaust part includes a plurality of exhaust holes 28, and the plurality of exhaust holes 28 are evenly disposed on the bonding layer 15 in FIG. 6, to form the non-closed bonding layer 24 having the plurality of exhaust holes 28. The black dot represents a position of the non-closed bonding layer 24, and the thin solid line represents the position of the periphery 22 of the first temporary carrier 8 or the position of the periphery 22 of the second temporary carrier 9.

The plurality of exhaust holes 28 are evenly disposed on the bonding layer 15 in FIG. 6, to form the non-closed bonding layer 24 having the plurality of exhaust holes 28, so that intervals of any two pairs of adjacent exhaust holes 28 in the plurality of the exhaust holes 28 are the same, so as to make stress distribution on surfaces of the first temporary carrier 8 and the second temporary carrier 9 relatively even.

As shown in FIG. 16, in an implementation of at least one embodiment of the present application, the non-closed bonding layer 24 includes a first non-closed bonding layer 25 and a second non-closed bonding layer 26. A shape of the first non-closed bonding layer 25 is circular, and the second non-closed bonding layer 26 is disposed at an interior enclosed by the first non-closed bonding layer 25. A cavity located at the interior enclosed by the first non-closed bonding layer 25 is equally divided into at least four equally-divided bonding cavities 23 by the second non-closed bonding layer 26 along a direction parallel to a sidewall of the first non-closed bonding layer 25. The exhaust part includes a plurality of exhaust grooves 27, and the plurality of exhaust grooves 27 are disposed at a middle position of the first non-closed bonding layer 25 and a middle position of the second non-closed bonding layer 26, respectively, to form the non-closed bonding layer 24. The thick solid line represents a position of the non-closed bonding layer 24, and the thin solid line represents a position of a periphery 22 of the first temporary carrier 8 or a position of a periphery 22 of the second temporary carrier 9.

The first non-closed bonding layer 25 is circumferentially disposed along the position of the periphery 22 of the first temporary carrier 8 or the position of the periphery 22 of the second temporary carrier 9, the second non-closed bonding layer 26 is disposed at the interior enclosed by the first non-closed bonding layer 25, and the interior enclosed by the first non-closed bonding layer 25 is divided into regions by the second non-closed bonding layer 26, so as to bond the first temporary carrier 8 and the second temporary carrier 9 into the integral composite panel. The cavity located at the interior enclosed by the first non-closed bonding layer 25 is equally divided into at least four equally-divided bonding cavities 23 by the second non-closed bonding layer 26 along the direction parallel to the sidewall of the first non-closed bonding layer 25, and the exhaust groove 27 is disposed at a center position of an interior of the first non-closed bonding layer 25, so that integral package with a relatively large area can be achieved, which further improves package efficiency, thus reducing a package cost, and problems of warping in products are effectively solved while solving the technical problems of easy bulging of a package structure and explosion of a vacuum bonding cavity, thus improving security of chip package and yield of products.

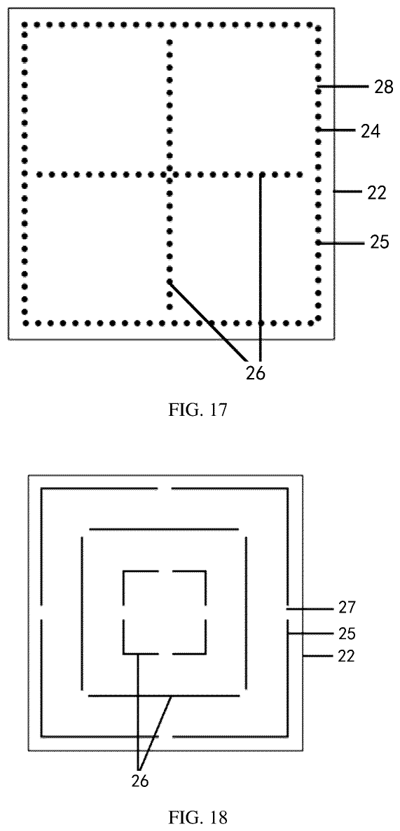

As shown in FIG. 17, in an implementation of at least one embodiment of the present application, a cavity located at an interior enclosed by the first non-closed bonding layer 25 is equally divided into at least four equally-divided bonding cavities 23 by the second non-closed bonding layer 26 along a direction parallel to a sidewall of the first non-closed bonding layer 25. The exhaust part includes a plurality of exhaust holes 28, the plurality of exhaust holes 28 are evenly disposed on the first non-closed bonding layer 25 and the second non-closed bonding layer 26, to form the non-closed bonding layer 24. The black dot represents a position of the non-closed bonding layer 24, and the thin solid line represents a position of a periphery 22 of the first temporary carrier 8 or a position of a periphery 22 of the second temporary carrier 9. The first non-closed bonding layer 25 is circumferentially disposed along the position of the periphery 22 of the first temporary carrier 8 or the position of the periphery 22 of the second temporary carrier 9, a second non-closed bonding layer 26 is disposed at the interior enclosed by the first non-closed bonding layer 25, and the interior enclosed by the first non-closed bonding layer 25 is divided into regions by the second non-closed bonding layer 26, so as to bond the first temporary carrier 8 and the second temporary carrier 9 into the integral composite panel. The cavity located at the interior enclosed by the first non-closed bonding layer 25 is equally divided into at least four equally-divided bonding cavities 23 by the second non-closed bonding layer 26 along the direction parallel to the sidewall of the first non-closed bonding layer 25, and the exhaust hole 28 is disposed at a center position of an interior of the first non-closed bonding layer 25, so that the plurality of bonding cavities 23 are in communication with each other. In this way, integral package with a relatively large area can be achieved, which further improves package efficiency, thus reducing a package cost, and problems of warping in products are effectively solved while solving the technical problems of easy bulging of a package structure and explosion of a vacuum bonding cavity, thus improving security of chip package and yield of products.

As shown in FIG. 18, in an implementation of at least one embodiment of the present application, a plurality of rectangular second non-closed bonding layers 26 with different sizes are disposed centered on a center point of an interior enclosed by a first non-closed bonding layer 25. The exhaust part includes a plurality of exhaust grooves 27, the plurality of exhaust grooves 27 are disposed at middle positions of the first non-closed bonding layer 25, and the plurality of exhaust grooves 27 are disposed at middle positions of the second non-closed bonding layer 26 or four corners of the second non-closed bonding layer 26, so as to form the non-closed bonding layer 24. The first non-closed bonding layer 25 is circumferentially disposed along a position of a periphery 22 of the first temporary carrier 8 or a position of a periphery 22 of the second temporary carrier 9, the second non-closed bonding layer 26 is disposed at the interior enclosed by the first non-closed bonding layer 25, and the interior enclosed by the first non-closed bonding layer 25 is divided into regions by the second non-closed bonding layer 26, so as to bond the first temporary carrier 8 and the second temporary carrier 9 into the integral composite panel. The plurality of rectangular second non-closed bonding layers 26 with different sizes are disposed centered on a center point of the interior enclosed by the first non-closed bonding layer 25, so that integral package with a relatively large area can be achieved, which further improves package efficiency, thus reducing a package cost, and problems of warping in products are effectively solved while solving the technical problems of easy bulging of a package structure and explosion of a vacuum bonding cavity, thus improving security of chip package and yield of products.

Manners of disposing the second non-closed bonding layer 26 are not limited to the manners shown in FIG. 15 to FIG. 18, and changes in a shape of the second non-closed bonding layer 26 fall within the protection scope of the present application.

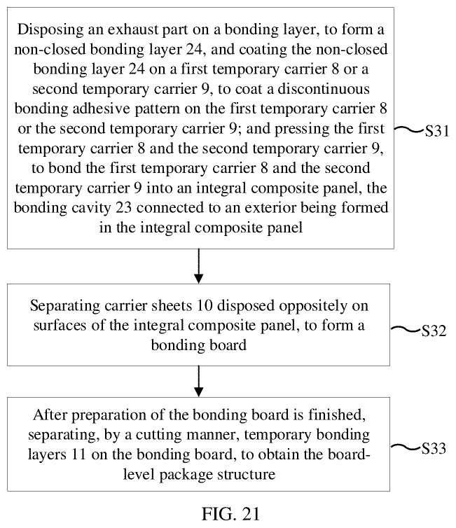

At least one embodiment of the present application provides a method for preparing a panel-level package structure, and referring to FIG. 12 to FIG. 18 and FIG. 21, the method includes the following steps S31 to S33.

S31: disposing an exhaust part on a bonding layer, to form a non-closed bonding layer 24, and coating the non-closed bonding layer 24 on a first temporary carrier 8 or a second temporary carrier 9, to coat a discontinuous bonding adhesive pattern on the first temporary carrier 8 or the second temporary carrier 9; and pressing the first temporary carrier 8 and the second temporary carrier 9, to bond the first temporary carrier 8 and the second temporary carrier 9 into an integral composite panel, the bonding cavity 23 connected to an exterior being formed in the integral composite panel. The exhaust part is disposed on the non-closed bonding layer 24, so that an air pressure inside the bonding cavity 23 and an air pressure outside the bonding cavity 23 are consistent.

S32: separating carrier sheets 10 disposed oppositely on surfaces of the integral composite panel, to form a bonding board.

S33: after preparation of the bonding board is finished, separating, by a cutting manner, temporary bonding layers 11 on the bonding board, to obtain the panel-level package structure.

The step S21 in the method shown in FIG. 20 includes: coating a non-closed bonding layer 24 circumferentially along a position of a periphery 22 of the first temporary carrier 8 or a position of a periphery 22 of the second temporary carrier 9; or coating a first non-closed bonding layer 25 circumferentially along a position of a periphery 22 of the first temporary carrier 8 or a position of a periphery 22 of the second temporary carrier 9, and disposing a second non-closed bonding layer 26 at an interior enclosed by the first non-closed bonding layer 25, the interior enclosed by the first non-closed bonding layer 25 being divided into regions by the second non-closed bonding layer 26.

In a vacuum negative pressure environment, the first temporary carrier 8 and the second temporary carrier 9 are pressed by a vacuum bonding device, which can make an interior of a bonding cavity 23 have a vacuum negative pressure during a pressing process, and an exhaust part is disposed on the bonding layer 15, which makes an air pressure inside the bonding cavity 23 and an air pressure outside the bonding cavity 23 consistent.

The panel-level package structure with a connection between an interior and an exterior and the method for preparing the same provided by the present application have the following beneficial effects.

Firstly, according to the panel-level package structure provided by at least one embodiment of the present application, the bonding layer is disposed between the first temporary carrier and the second temporary carrier, so that integral package with a relatively large area can be achieved by the first temporary carrier, the second temporary carrier and the bonding layer, which further improves package efficiency, thus reducing a package cost.

Secondly, according to the panel-level package structure provided by at least one embodiment of the present application, the panel-level fan-out package structure with a double-sided symmetrical design is adopted, so that during a preparing process, products are evenly stressed, which not only effectively solves problems of warping in products, but also greatly improves preparing efficiency, thus reducing a cost.

Thirdly, according to the panel-level package structure provided by at least one embodiment of the present application, every two temporary carriers are bonded together, to obtain an integral composite panel enclosed on all sides. Each side of the first temporary carrier and each side of the second temporary carrier have tension after the first temporary carrier and the second temporary carrier are bonded together, so that the integral composite panel has a good flatness, which further improves problems of warping in products.

Fourthly, according to the panel-level package structure provided by at least one embodiment of the present application, the bonding layer is connected to both the first temporary carrier and the second temporary carrier, so that the bonding cavity may be formed in the integral composite panel. The structure obtained after the multiple circuit layers are formed on the panel-level fan-out package structure is separated along the bonding cavity, and therefore, disposal of the bonding cavity not only makes a separation effect good, but also improves separation efficiency.

Lastly, according to the panel-level package structure with a connection between an interior and an exterior provided by at least one embodiment of the present application, the non-closed bonding layer enclosed on all sides and having an exhaust part is disposed between two temporary carriers, so that the integral composite panel with a connection between an interior and an exterior and with an equivalent pressure is formed by the two temporary carriers, which solves the technical problems of explosion of a bonding cavity and bulging of a bonding cavity in a high-temperature baking environment, thus improving security of chip package and yield of products.

It should be understood that the present application is described by some embodiments, as a person skilled in the art knows, without departing from the spirit and scope of the present application, various changes or equivalent replacements can be made to these features and embodiments. In addition, under the teaching of the present application, these features and embodiments may be modified to adapt to specific situations and materials without departing from the spirit and scope of the present application. Therefore, the present application is not limited by the specific embodiments disclosed herein, various changes or equivalent replacements may fall within the scope of the claims of the present application, and all the embodiments falling within the scope of the claims of the present application fall within the protection scope of the present application.

What is claimed is:

1. A panel-level package structure, comprising:
at least one bonding layer; and a first temporary carrier and a second temporary carrier oppositely disposed on both sides of the at least one bonding layer,
wherein both the first temporary carrier and the second temporary carrier are connected to the at least one bonding layer, and at least one bonding cavity is jointly formed by the at least one bonding layer, the first temporary carrier and the second temporary carrier.

2. The panel-level package structure according to claim 1, wherein the first temporary carrier is connected to the second temporary carrier through the at least one bonding layer, to form an integral composite panel, and the integral composite panel is flat.

3. The panel-level package structure according to claim 1, wherein the at least one bonding layer comprises a first bonding layer, and the first bonding layer is circumferentially disposed along a position of a periphery of the first temporary carrier or a position of a periphery of the second temporary carrier.

4. The panel-level package structure according to claim 3, wherein the at least one bonding layer further comprises a second bonding layer, the second bonding layer is disposed at an interior enclosed by the first bonding layer, and a cavity located at the interior enclosed by the first bonding layer is divided into regions by the second bonding layer.

5. The panel-level package structure according to claim 4, wherein the cavity located at the interior enclosed by the first bonding layer is equally divided into at least four equally-divided bonding cavities by the second bonding layer.

6. The panel-level package structure according to claim 4, wherein the cavity located at the interior enclosed by the first bonding layer is equally divided into two equally-divided bonding cavities by the second bonding layer along a direction of a diagonal of the interior enclosed by the first bonding layer.

7. The panel-level package structure according to claim 4, wherein at least one rectangular second bonding layer is disposed centered on a center point of the interior enclosed by the first bonding layer.

8. The panel-level package structure according to claim 4, wherein four corners of the interior enclosed by the first bonding layer are respectively disposed with the second bonding layer having a rectangular shape.

9. The panel-level package structure according to claim 1, wherein the at least one bonding layer adopts a closed structure, and an interior of the at least one bonding cavity has a vacuum negative pressure.

10. The panel-level package structure according to claim 1, wherein the at least one bonding layer adopts a non-closed structure, and an exhaust part is disposed on the at least one bonding layer, so that an air pressure inside the at least one bonding cavity and an air pressure outside the at least one bonding cavity are consistent.

11. The panel-level package structure according to claim 10, wherein the exhaust part comprises a plurality of exhaust grooves, and the plurality of exhaust grooves are disposed at four corners of the at least one bonding layer or at a middle position of the at least one bonding layer or at a center position of an interior of the at least one bonding layer.

12. The panel-level package structure according to claim 10, wherein the exhaust part comprises a plurality of exhaust holes, and the plurality of exhaust holes are evenly disposed on the at least one bonding layer or disposed at a center position of an interior of the at least one bonding layer.

13. The panel-level package structure according to claim 1, wherein the first temporary carrier and the second temporary carrier respectively comprise a plastic package layer, a chip is disposed on the plastic package layer, and a plurality of chip conductive bumps are connected to the chip.

14. The panel-level package structure according to claim 13, wherein an insulating layer and a carrier sheet are sequentially disposed on the plastic package layer, and at least two chips are disposed between the insulating layer and the plastic package layer.

15. The panel-level package structure according to claim 1, wherein a structure of the first temporary carrier and a structure of the second temporary carrier are the same, the first temporary carrier and the second temporary carrier are disposed in parallel, and the first temporary carrier and the second temporary carrier are symmetric relative to the at least one bonding layer.

16. A method for preparing a panel-level package structure, comprising:
coating at least one bonding layer on a first temporary carrier or a second temporary carrier, and pressing the first temporary carrier and the second temporary carrier into an integral composite panel, wherein an interior of the integral composite panel comprises at least one bonding cavity jointly formed by the at least one bonding layer, the first temporary carrier and the second temporary carrier.

17. The method for preparing the panel-level package structure according to claim 16, further comprising:
separating carrier sheets oppositely disposed on surfaces of the integral composite panel, to form a bonding board; and
after preparation of the bonding board is finished, separating, by a cutting manner, temporary bonding layers on the bonding board, to obtain the panel-level package structure.

18. The method for preparing the panel-level package structure according to claim 16, wherein in a case that the at least one bonding layer comprises a first bonding layer, the coating at least one bonding layer on a first temporary carrier or a second temporary carrier comprises:
coating the first bonding layer circumferentially along a position of a periphery of the first temporary carrier or a position of a periphery of the second temporary carrier; or
in a case that the at least one bonding layer comprises a first bonding layer and a second bonding layer, the coating at least one bonding layer on a first temporary carrier or a second temporary carrier comprises:
coating the first bonding layer circumferentially along a position of a periphery of the first temporary carrier or a position of a periphery of the second temporary carrier, and disposing the second bonding layer at an interior enclosed by the first bonding layer, the interior enclosed by the first bonding layer being divided into regions by the second bonding layer.

19. The method for preparing the panel-level package structure according to claim 16, wherein the at least one bonding layer adopts a closed structure, and an interior of the at least one bonding cavity has a vacuum negative pressure; or
the at least one bonding layer adopts a non-closed structure, and an exhaust part is disposed on the at least one bonding layer, so that an air pressure inside the at least one bonding cavity and an air pressure outside the at least one bonding cavity are consistent.

20. The method for preparing the panel-level package structure according to claim 16, wherein the pressing the first temporary carrier and the second temporary carrier into an integral composite panel comprises:
closing and pressing the first temporary carrier and the second temporary carrier by a vacuum bonding device, so that the at least one bonding cavity is capable of being formed between the first temporary carrier and the second temporary carrier.
